(19) United States
(12) Patent Application Publication
(10) Pub. No.: US 2024/0152054 A1
(43) Pub. Date: May 9, 2024

(54) ASYMMETRIC UV EXPOSURE METHOD

(71) Applicant: FLEXTOUCH TECHNOLOGIES CO., LTD., Jiaxing City (CN)

(72) Inventors: Jun WANG, Jiaxing City (CN); Tengwei HUANG, Jiaxing City (CN); Jiang LIU, Jiaxing City (CN); Jonathan JIANG, Jiaxing City (CN)

(21) Appl. No.: 17/769,291

(22) PCT Filed: Jun. 17, 2021
(86) PCT No.: PCT/CN2021/100610

§ 371 Date: Apr. 14, 2022

(30) Foreign Application Priority Data
Feb. 9, 2021 (CN) 202110178400.1

(51) Int. Cl. G03F 7/20; G03F 7/00; G03F 7/004; G03F 7/038

(52) U.S. Cl. CPC G03F 7/2004; G03F 7/0035; G03F 7/0045; G03F 7/038; G06F 2203/04103

(57) ABSTRACT

An asymmetric UV exposure method, and a metal mesh sensor manufactured using the same are described. The method includes applying a UV-curable coating #1 on one side of an optically transparent substrate; applying a UV-curable coating #2 on the other side of the optically transparent substrate; and exposing both sides of the optically transparent substrate to UV light simultaneously. The UV-curable coating #1 and the UV-curable coating #2 have UV absorption peaks at different wavelengths. The method not only allows a greater choice of optically transparent substrates for manufacturing metal mesh touch sensors, but also enables better flexibility and improved optical properties.

### CROSS-REFERENCE TO RELATED APPLICATIONS

This application claims the priority of patent application No. CN202110178400.1, entitled “ASYMMETRIC UV EXPOSURE METHOD” and filed on Feb. 9, 2021, which is incorporated in its entirety herein by reference.

### TECHNICAL FIELD

The invention relates to an asymmetric Ultraviolet (UV) exposure method, and more particularly, to an asymmetric UV exposure method applicable to an optically transparent substrate (with or without UV blocking functions).

### BACKGROUND

A metal mesh-based touch sensor, which is advantageous for superior flexibility, excellent optical performance, and low manufacturing costs, includes an optically transparent substrate as a key component. According to the current process, the optically transparent substrate is required to have a UV blocking function (e.g., a blocking rate of more than 90% at a certain UV wavelength) so that UV light does not pass through the substrate from one side to cure the coating on the other side. In the current processes, the same UV-curable coatings are applied on both sides of the substrate and exposed to UV light with the same peak wavelength (as shown in FIG. 1). The UV blocking function of the optically transparent substrate plays a key role in blocking the UV light from passing through the substrate, allowing unique micropatterns to be formed on each side of the substrate.

In the current manufacturing processes, the available selectable substrates are very limited due to the mandatory requirement for the UV blocking function of optically transparent substrates. Introducing the UV blocking function into optically transparent substrates requires development work by the substrate suppliers and often sacrifices the optical properties of the substrates, resulting in for example lower light transmittance and higher haze, which is undesirable for applications of metal mesh touch sensors. Currently, few polyethylene terephthalate (PET) products have UV blocking functions, and emerging substrates such as cyclic olefin polymers (COP) and colorless polyimide (CPI) have no UV blocking function at all, which hinders the development of flexible devices such as metal mesh touch sensors.

### SUMMARY

The object of the invention is to overcome the above-mentioned drawbacks of the prior art and provide an asymmetric UV exposure method in which the UV blocking function of the optically transparent substrate is not necessary, and thus more selectable optically transparent substrates are available.

In one aspect, the invention provides an asymmetric UV exposure method comprising: applying a first UV-curable coating on one side of an optically transparent substrate, applying a second UV-curable coating on the other side of the optically transparent substrate, and exposing both sides of the optically transparent substrate to UV light simultaneously, where the first UV-curable coating has a UV absorption peak at a wavelength different from that at which the second UV-curable coating has a UV absorption peak.

In one embodiment, the wavelength of the UV absorption peak of the first UV-curable coating differs from the wavelength of the UV absorption peak of the second UV-curable coating by at least 10 nm.

In one embodiment, the first and second UV-curable coatings are each independently selected from the group consisting of a positive photoresist and a negative photoresist.

In one embodiment, the positive photoresist includes a post-exposure developer-soluble resin material, and the negative photoresist includes post-exposure developer-insoluble resin material.

In one embodiment, the first and second UV-curable coatings each include a photoinitiator.

In one embodiment, the photoinitiators of the first and second UV-curable coatings are each independently at least one selected from the group consisting of acetophenone-based compounds, benzophenone-based compounds, triazine-based compounds, thioxanthone-based compounds and oxime ester-based compounds.

In one embodiment, the wavelength difference between the UV absorption peaks of the first and second UV-curable coatings is achieved by using two different photoinitiators having UV absorption peaks at different wavelengths.

In one embodiment, the optically transparent substrate is made of PET, COP, CPI, or other flexible or rigid material.

In one embodiment, the optically transparent substrate is free of a UV blocking function.

In another aspect, the invention further provides a metal mesh touch sensor manufactured by the above asymmetric UV exposure method.

The advantages of the technical solution of the invention at least lie in that: (1) no UV blocking function is required in optically transparent substrates; (2) more selectable optically transparent substrates are available; (3) the method of the disclosure is applicable to both positive UV curable photoresists and negative UV-curable photoresists; and (4) products such as flexible devices manufactured using this method have improved optical properties.

### BRIEF DESCRIPTION OF THE DRAWINGS

The accompanying drawings which constitute a part of the specification are used to provide a further understanding of the invention, and explain the invention together with the detailed description below, but do not constitute limitations to the invention, in which:

FIG. 1 shows a conventional UV exposure method in which same UV-curable coatings are applied on both sides of the substrate and exposed to UV light having the same peak wavelength;

FIG. 2 shows the novel asymmetric UV exposure method according to the invention, where UV-curable coating #1 is applied on one side of an optically transparent substrate, and UV-curable coating #2 is applied on the other side of the optically transparent substrate;

FIG. 3 shows the network structure of the photoresist of the first group after development according to an embodiment of the invention;

FIG. 4 shows the copper mesh structure of the photoresist of the first group after copper plating according to an embodiment of the invention;

FIG. 5 shows the network structure of the photoresist of the second group after development according to an embodiment of the invention;

FIG. 6 shows the copper mesh structure of the photoresist of the second group after copper plating according to an embodiment of the invention;

FIG. 7 shows the copper mesh structure formed by the photoresist of the third group on side #1 after exposure and copper plating;

FIG. 8 shows the copper mesh structure formed by the photoresist of the third group on side #2 after exposure and copper plating;

FIG. 9 shows the copper mesh structure formed by the photoresist of the fourth group on side #1 after exposure and copper plating;

FIG. 10 shows the copper mesh structure formed by the photoresist of the fourth group on side #2 after exposure and copper plating;

FIG. 11 shows the copper mesh structure formed by the photoresist of the fifth group on side #1 after exposure and copper plating;

FIG. 12 shows the copper mesh structure formed by the photoresist of the fifth group on side #2 after exposure and copper plating;

FIG. 13 shows the copper mesh structure formed by the photoresist of the sixth group on side #1 after exposure and copper plating; and

FIG. 14 shows the copper mesh structure formed by the photoresist of the sixth group on side #2 after exposure and copper plating.

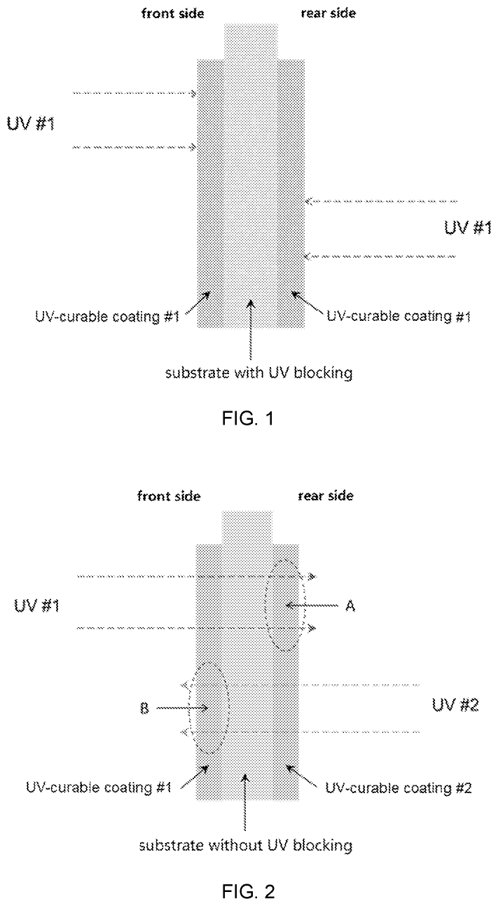

### DETAILED DESCRIPTION

Hereinafter, specific embodiments of the invention will be described in detail. It should be understood that the specific embodiments described herein are only used to illustrate and explain the invention, but not to limit the invention.

The endpoints and any value of the ranges disclosed herein are not limited to the exact ranges or values, and these ranges or values should be construed as including values close to these ranges or values. For numerical ranges, the endpoint values of each range, the endpoint values and the individual point values of each range, or the individual point values of each range can be combined with each other to obtain one or more new numerical ranges which should be regarded as being specifically disclosed herein.

It should be understood that although the terms “first”, “second”, etc. may be used herein to describe various elements, these elements should not be limited by these terms. These terms are only used to distinguish one element from another. For example, a first element could be named as a second element, and, similarly, a second element could be named as a first element, without departing from the scope of the invention.

All terms (including technical and scientific terms) used herein have the same meanings as commonly understood by one of ordinary skill in the art to which this invention belongs, unless otherwise defined. It should also be understood that terms such as those defined in commonly used dictionaries should be construed to have meanings consistent with their meanings in the context of the related art, and not be construed in idealized or overly formalized meanings, unless clearly defined herein.

In one aspect, the invention provides an asymmetric UV exposure method comprising: applying a UV-curable coating #1 on one side of an optically transparent substrate; applying a UV-curable coating #2 on the other side of the optically transparent substrate; and exposing both sides of the optically transparent substrate to UV light simultaneously, where the UV-curable coating #1 and the UV-curable coating #2 have UV absorption peaks at different wavelengths.

Since the UV-curable coating #1 and the UV-curable coating #2 have UV absorption peaks at different wavelengths, the asymmetric UV exposure method of the invention does not require the optically transparent substrate to have UV blocking functions, and due to the mismatch between the wavelength of the UV light and the wavelength of the absorption peak of the UV-curable coating, the UV-curable coating on the other side would not be cured by the UV light passing through the substrate. Thus, with the asymmetric UV exposure implemented according to the invention, each of the two sides of the optically transparent substrate to which different UV-curable coatings (e.g., UV-curable coating #1 and UV-curable coating #2) are applied can be exposed to its corresponding UV absorption wavelength (e.g., UV #1 and UV #2), so as to achieve simultaneous exposure of both sides of the optically transparent substrate (as shown in FIG. 2). As used herein, the term “UV blocking function” refers to the ability of an optically transparent substrate to block the transmission of ultraviolet light.

As is known in the art, the wavelength of the UV absorption peak according to the invention is generally in the range of 190 nm to 400 nm. In addition, according to the invention, the wavelength difference between the UV absorption peaks of the UV-curable coating #1 and the UV-curable coating #2 may have a minimum value so as to ensure a certain degree of mismatch between the wavelength of the UV light and the wavelength of the absorption peak of the UV-curable coating. In a preferred embodiment, the wavelength of the UV absorption peak of the UV-curable coating #1 may differ from the wavelength of the UV absorption peak of the UV-curable coating #2 by at least 10 nm, for example, 20 nm, 30 nm, 40 nm, 50 nm, 60 nm, 80 nm or 100 nm.

According to the invention, the UV-curable coating of the invention is not particularly limited, and may be a photoresist commonly used in the art. In a preferred embodiment, the UV-curable coating #1 and the UV-curable coating #2 are each independently selected from the group consisting of a positive photoresist and a negative photoresist. In other words, both the UV-curable coating #1 and the UV-curable coating #2 may be positive photoresists; both the UV-curable coating #1 and the UV-curable coating #2 may be negative photoresists; or one of the UV-curable coating #1 and the UV-curable coating #2 is a positive photoresist and the other is a negative photoresist.

In addition, the type of the photoresist can be further selected according to actual needs. In one embodiment, the positive photoresist may preferably contain a post-exposure developer-soluble resin material, and the negative photoresist may preferably contain a post-exposure developer-insoluble resin material. The developer is usually an aqueous solution containing an alkaline compound and a surfactant. The alkaline compound can be an inorganic or organic alkaline compound, and these inorganic and organic alkaline compounds can be used alone or in combination of two or more; and as the surfactant, at least one selected from the group consisting of nonionic surfactants, anionic surfactants and cationic surfactants can be used, and these surfactants can be used alone or in combination of two or more.

According to the invention, the UV-curable coating #1 and the UV-curable coating #2 may each contain a photoinitiator (also known as a sensitizer or a photosensitizer, etc.) so as to allow the UV-curable coating #1 and the UV-curable coating #2 to have UV absorption peaks at different wavelengths. In one embodiment, the wavelength difference between the UV absorption peaks of the UV-curable coating #1 and the UV-curable coating #2 can be achieved by using two different photoinitiators having UV absorption peaks at different wavelengths. Therefore, the UV-curable coating #1 and the UV-curable coating #2 of the invention typically contain different photoinitiators.

Further, the type of the photoinitiator of the invention is not particularly limited, and may be a common photoinitiator in the art. In a preferred embodiment, the photoinitiators of the UV-curable coating #1 and the UV-curable coating #2 are each at least one selected from the group consisting of acetophenone-based compounds, benzophenone-based compounds, triazine-based compounds, thioxanthone-based compounds and oxime ester-based compounds. Specific examples of the acetophenone-based compound may include 2-hydroxy-2-methyl-1-phenylpropan-1-one, diethoxyacetophenone, 2-(4-methylbenzyl)-2-(dimethylamino)-1-(4-morpholinophenyl)butan-1-one and the like. Specific examples of the benzophenone-based compound may include benzophenone, methyl 2-benzoylbenzoate, 4-benzoyl-4′-methyldiphenyl sulfide, 2,4,6-trimethylbenzophenone, and the like. Specific examples of the triazine-based compound may include 2,4-bis(trichloromethyl)-6-(4-methoxyphenyl)-1,3,5-triazine, 2,4-bis(trichloromethyl)-6-(4-methoxynaphthyl)-1,3,5-triazine, 2,4-bis(trichloromethyl)-6-[2-(3,4-dimethoxyphenyl)vinyl]-1,3,5-triazine, 2,4-bis(trichloromethyl)-6-2-(4-diethylamino-2-methylphenyl)vinyl]-1,3,5-triazine and the like. Specific examples of the thioxanthone-based compound may include 2-isopropylthioxanthone, 2,4-diethylthioxanthone, 2,4-dichlorothioxanthone, 1-chloro-4-propoxythioxanthone and the like. Specific examples of the oxime ester-based compound may include o-ethoxycarbonyl-a-oxyimino-1-phenylpropan-1-one, 1,2-octanedione, 1-(4-phenylthio)benzene, 2-(o-benzoyl oxime) and the like.

According to the invention, the optically transparent substrate may be a substrate having excellent transparency, mechanical strength, and thermal stability, and as a specific example, the optically transparent substrate may be made of at least one selected from: polyester-based resins such as PET, polyethylene naphthalate, polybutylene terephthalate, and the like; cellulose-based resins such as diacetyl cellulose, cellulose triacetate, and the like; acrylic resins such as polymethyl (meth)acrylate, polyethyl (meth)acrylate, and the like; styrene-based resins such as polystyrene, acrylonitrile styrene copolymer, and the like; polyolefin-based resins such as polyethylene, polypropylene, cyclic or norbornene-polyolefin, ethylene-polypropylene copolymers, and the like; vinyl chloride-based resins; amide-based resins such as nylon, aramid, and the like; polyether ether ketone-based resins; polyphenylene sulfide-based resins; vinyl alcohol-based resins; polyvinylidene chloride-based resins; vinyl butyral-based resins; epoxy-based resins, or some other novel materials such as COP, CPI, and the like. In a preferred embodiment, the optically transparent substrate is made of PET, COP, CPI, or other flexible or rigid materials.

According to the advantages of the asymmetric UV exposure method of the invention, the optically transparent substrate does not necessarily have UV blocking functions, which allows more selectable optically transparent substrates. Therefore, in a preferred embodiment, the optically transparent substrate may be a substrate without UV blocking functions.

Further, such a transparent optical film may appropriately contain one or more types of additives. For the additive, for example, the additive may be an UV absorber, an antioxidant, a lubricant, a plasticizer, a mold release agent, an anti-colorant, a flame retardant, a surfactant, an antistatic agent, a pigment, a colorant, or the like.

Furthermore, a thickness of such a transparent optical film can be appropriately determined, however, in general, the thickness can be determined in a range between 1 μm and 500 μm in consideration of the film's strength, processability and thin-layer properties. In particular, a value between 1 μm and 300 μm is preferred, and a value between 5 μm and 200 μm is more preferred.

As an example, the asymmetric UV exposure method as described can be used to produce a metal mesh touch sensor on an optically transparent substrate without UV blocking functions. The asymmetric UV exposure method is performed by first applying a UV-curable coating #1 (e.g., a negative photoresist) on one side of the optically transparent substrate and a UV-curable coating #2 (e.g., a negative photoresist) on the other side of the optically transparent substrate; then placing a particular photomask on each side of the optically transparent substrate during the step of UV exposure to form a desired cured UV coating on each side; then subjecting the optically transparent substrate with the cured micropattern on each side to wet development and metallization to form the metal mesh touch sensor. The asymmetric UV exposure method as described does not require the UV blocking function of the optically transparent substrate, thus allowing for greater choice of optically transparent substrates in applications including, but not limited to, the production of metal mesh touch sensors.

Thus, in another aspect, a metal mesh touch sensor manufactured by the asymmetric UV exposure method according to any one of the preceding claims. However, it should be noted that, as discussed above, the manufactured products may include, but are not limited to, metal mesh touch sensors, as well as other suitable optical materials or products.

Since introducing UV blocking functions into optically transparent substrates requires development work by the substrate suppliers and often sacrifices the optical properties of the substrates, such as lower light transmittance and higher haze, the UV exposure method of the invention not only allows a greater choice of optically transparent substrates for manufacturing metal mesh touch sensors, but also enables better flexibility and improved optical properties (i.e., higher light transmittance and lower haze).

The embodiments of the invention are described below by way of specific examples. Those who are familiar with this technology can easily acknowledge other advantages and effects of the invention from the contents disclosed in this specification. Obviously, the described examples are a part of, but not all of the examples of the invention. Based on the examples of the invention, all other embodiments obtained by those of ordinary skill in the art without creative efforts shall fall within the scope of the invention.

### EXAMPLES

A photoresist film was coated on the surface of each substrate using a Meyer rod or a gravure proofer, and then dried in an oven at a temperature of 50-100° C. for 120 seconds to obtain a coating with a thickness of 500-1000 nm; a layer of palladium colloid was applied on top of the photoresist film, and then a protective film was applied, and the photomask was UV exposed using different filters and energies; after exposure, the substrate was rinsed with a developer to remove the uncured coating, and was then dipped into an electroless copper bath to grow the copper mesh. Experiments were conducted for a total of six groups:

The first group: photoresist film BC002 (containing 0.8% of photoinitiator-1 having an absorption peak at a wavelength of 314 nm) was coated on one surface of the substrate;
the second group: photoresist film BCK (having an absorption peak at a wavelength of 365 nm) was coated on one surface of the substrate;
the third group: photoresist films BC001 (containing 1.26% of photoinitiator-1 having an absorption peak at a wavelength of 314 nm) were coated on both surfaces of the substrate;
the fourth group: photoresist films BCK were coated on both surfaces of the substrate;

The fifth group: photoresist film BC002 was coated on one surface of the substrate, and photoresist film BCK was coated on the other surface;

The sixth group: photoresist film BC003 (containing 0.6% of photoinitiator-1 having an absorption peak at a wavelength of 314 nm) was coated on one surface of the substrate, and photoresist film BCK was coated on the other surface.

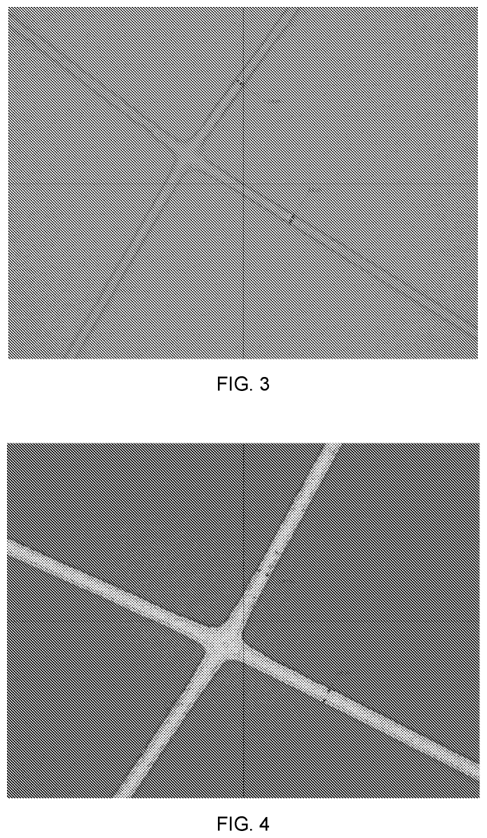

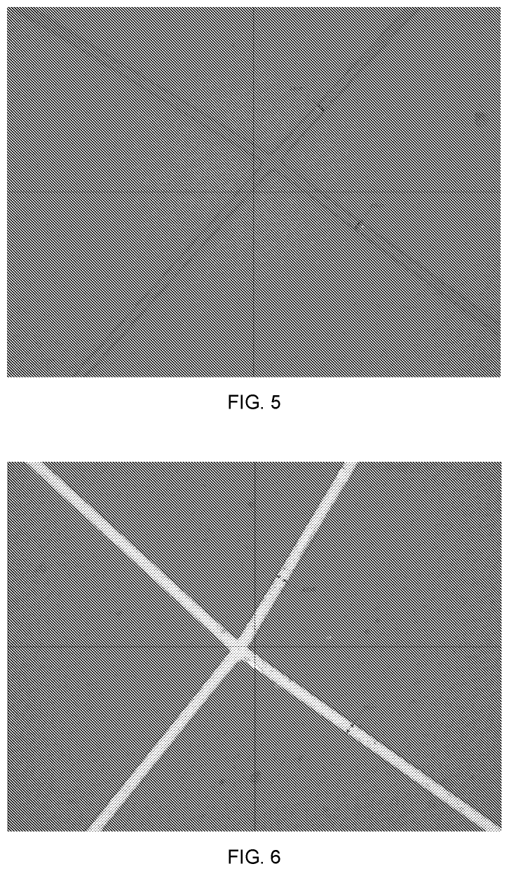

As a result, FIG. 3 and FIG. 4 show the mesh structure after development and the copper mesh structure after copper plating of the photoresist of the first group, respectively; and FIG. 5 and FIG. 6 show the mesh structure after development and the copper mesh structure after copper plating of the photoresist of the second group, respectively. As can be seen, when only one surface of the substrate is coated with the photoresist film, a regular mesh pattern can finally be formed.

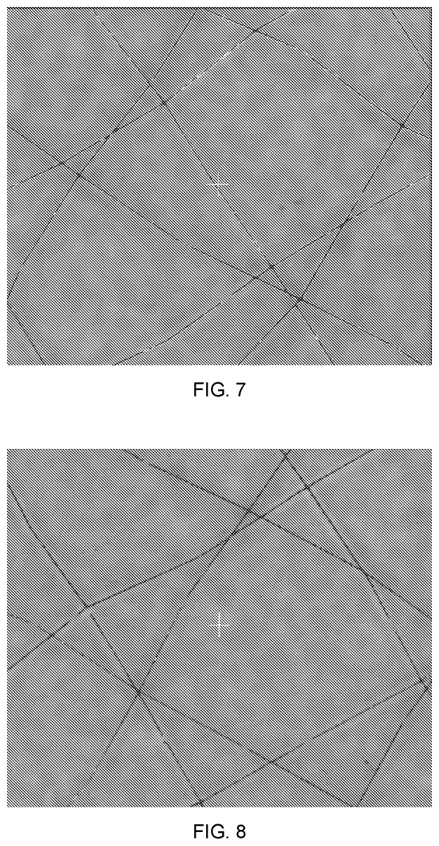

In addition, FIG. 7 and FIG. 8 show the copper mesh structures formed by the photoresist of the third group on side #1 and side #2 after exposure and copper plating, respectively. As can be seen, the copper mesh structures formed on both sides are messy, because when materials having absorption peaks at the same wavelength (the wavelength of the absorption peak on either side was 314 nm) are applied on both sides of the substrate, the photoresist on either side #1 or side #2 would be affected by the curing with the UV light having the same wavelength on the other side, that is, the UV light would interfere with the photoresist on the other side of the substrate, which is not desirable for the manufacture of metal mesh touch sensors.

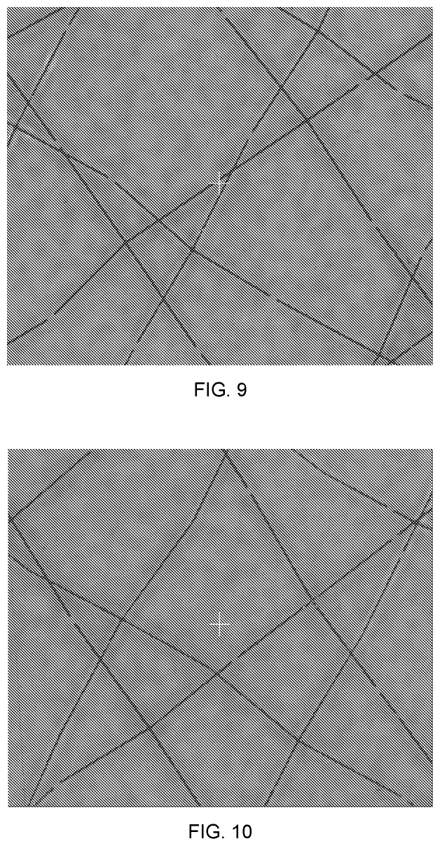

FIG. 9 and FIG. 10 show the copper mesh structures formed by the photoresist of the fourth group on side #1 and side #2 after exposure and copper plating, respectively. As can be seen, the copper mesh structures formed on both sides are messy, because when materials having absorption peaks at the same wavelength (the wavelength of the absorption peak on either side was 365 nm) are applied on both sides of the substrate, the photoresist on either side #1 or side #2 would be affected by the curing with the UV light having the same wavelength on the other side, that is, the UV light would interfere with the photoresist on the other side of the substrate, which is not desirable for the manufacture of metal mesh touch sensors.

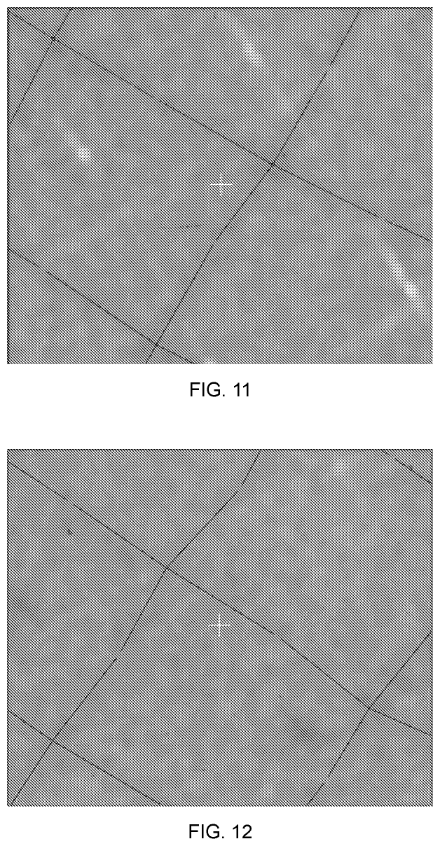

According to an embodiment of the invention, FIG. 11 and FIG. 12 show the copper mesh structures formed by the photoresists of the fifth group on side #1 and side #2 after exposure and copper plating, respectively. As can be seen, regular mesh patterns were formed on both sides, because when materials having absorption peaks at different wavelengths (the wavelength of the absorption peak was 314 nm on side #1, and 365 nm on side #2) are applied on two sides of the substrate, the photoresist on either side #1 or side #2 would not be affected by the curing with the UV light having a different wavelength on the other side, that is, the asymmetric UV exposure eliminates the effect of the UV light from the other side of the substrate.

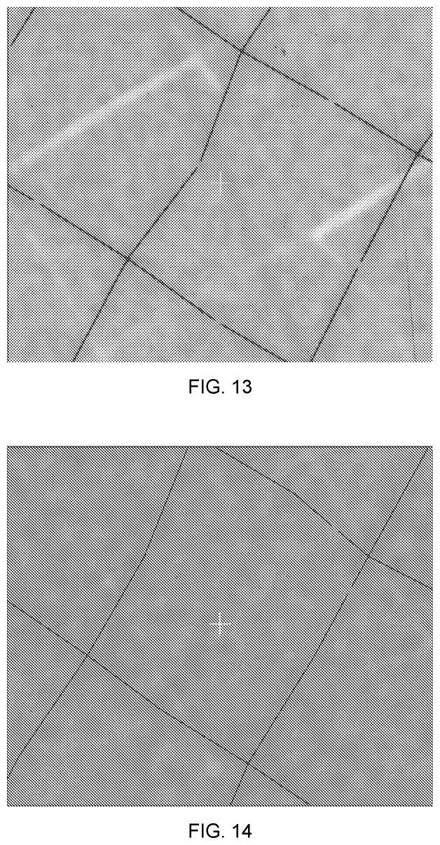

Similarly, FIG. 13 and FIG. 14 show the copper mesh structures formed by the photoresists of the sixth group on side #1 and side #2 after exposure and copper plating, respectively. As can be seen, regular mesh patterns were formed on both sides, because when materials having absorption peaks at different wavelengths (the wavelength of the absorption peak was 314 nm on side #1, and 365 nm on side #2) are applied on two sides of the substrate, the photoresist on either side #1 or side #2 would not be affected by the curing with the UV light having a different wavelength on the other side, that is, the asymmetric UV exposure eliminates the effect of the UV light from the other side of the substrate.

The preferred embodiments of the invention have been described in detail above, but the invention is not limited to the specific details in the above-mentioned embodiments. Within the scope of the technical concept of the invention, various simple modifications can be made to the technical solutions of the invention, which all belong to the protection scope of the invention.

In addition, it should be noted that the specific technical features described in the above-mentioned specific embodiments can be combined in any suitable way on a consistent basis, and the possible combinations will not be described separately.

In addition, the various embodiments of the invention can also be combined in any way without departing from the spirit of the invention, and the combinations should also be regarded as within the disclosure of the invention.

This listing of claims replaces all prior versions, and listings of claims in the application:

1. An asymmetric UV exposure method comprising:
applying a first UV-curable coating on one side of an optically transparent substrate,
applying a second UV-curable coating on the other side of the optically transparent substrate, and
exposing both sides of the optically transparent substrate to UV light simultaneously,
wherein the first UV-curable coating has a UV absorption peak at a wavelength different from that at which the second UV-curable coating has a UV absorption peak.

2. The asymmetric UV exposure method of claim 1, wherein the wavelength of the UV absorption peak of the first UV-curable coating differs from the wavelength of the UV absorption peak of the second UV-curable coating by at least 10 nm.

3. The asymmetric UV exposure method of claim 1, wherein the first and second UV-curable coatings are each independently selected from the group consisting of a positive photoresist and a negative photoresist.

4. The asymmetric UV exposure method of claim 3, wherein the positive photoresist comprises a post-exposure developer-soluble resin material, and the negative photoresist comprises a post-exposure developer-insoluble resin material.

5. The asymmetric UV exposure method of claim 1, wherein the first and second UV-curable coatings each comprise a photoinitiator.

6. The asymmetric UV exposure method of claim 5, wherein the photoinitiators of the first and second UV-curable coatings are each independently at least one selected from the group consisting of acetophenone-based compounds, benzophenone-based compounds, triazine-based compounds, thioxanthone-based compounds and oxime ester-based compounds.

7. The asymmetric UV exposure method of claim 5, wherein the wavelength difference between the UV absorption peaks of the first and second UV-curable coatings is achieved by using two different photoinitiators having UV absorption peaks at different wavelengths.

8. The asymmetric UV exposure method of claim 1, wherein the optically transparent substrate is made of PET, COP, CPI, or other flexible or rigid material.

9. The asymmetric UV exposure method of claim 1, wherein the optically transparent substrate is free of a UV blocking function.

10. A metal mesh touch sensor manufactured by the asymmetric UV exposure method according to claim 1.

11. The asymmetric UV exposure method of claim 6, wherein the wavelength difference between the UV absorption peaks of the first and second UV-curable coatings is achieved by using two different photoinitiators having UV absorption peaks at different wavelengths.

12. The asymmetric UV exposure method of claim 8, wherein the optically transparent substrate is free of a UV blocking function.
